(19) United States
(12) Patent Application Publication
(10) Pub. No.: US 2026/0354181 A1
(43) Pub. Date: Nov. 5, 2026

(54) SEMICONDUCTOR PACKAGES AND METHODS OF FORMING THE SAME

(71) Applicant: Taiwan Semiconductor Manufacturing Company, Ltd., Hsinchu (TW)

(72) Inventors: Chen Sheng Wu, Hsinchu (TW); Ming-Tsu Chung, Hsinchu City (TW); Yu-Han Wang, Hsinchu (TW); Yung-Chi Lin, New Taipei City (TW); Hsiang Liu, Hsinchu (TW); Chia-Hao Hsu, Hsinchu (TW); Ken-Yu Chang, Hsinchu City (TW); Chien-Hao Chung, Hsinchu City (TW); Chia-Fang Tsai, Hsinchu County (TW)

(73) Assignee: Taiwan Semiconductor Manufacturing Company, Ltd., Hsinchu (TW)

(21) Appl. No.: 19/196,690

(22) Filed: May 1, 2025

(51) Int. Cl. H10W 40/25; H10W 72/00; H10W 90/00; H10W 99/00

(52) U.S. Cl. CPC H10W 40/257; H10W 40/255; H10W 99/00; H10W 72/07331; H10W 90/734

(57) ABSTRACT

A semiconductor package includes a heat dissipation substrate and an integrated circuit structure. The heat dissipation substrate includes a substrate having a plurality of recesses at a first surface thereof, a filling layer disposed in the recesses at the first surface, and a first bonding layer disposed on the filling layer. The integrated circuit structure includes at least one die and a second bonding layer on the at least one die. The integrated circuit structure is bonded to the heat dissipation substrate through the first bonding layer and the second bonding layer.

### BACKGROUND

In recent years, the semiconductor industry has experienced rapid growth due to continuous improvement in integration density of various electronic components, e.g., transistors, diodes, resistors, capacitors, etc. For the most part, this improvement in integration density has come from successive reductions in minimum feature size, which allows more components to be integrated into a given area. Although the existing semiconductor packages have been generally adequate for their intended purposes, they have not been entirely satisfactory in all respects. For example, the heat dissipation is a challenge in a variety of semiconductor packages.

### BRIEF DESCRIPTION OF THE DRAWINGS

FIG. 1 to FIG. 11 are schematic cross-sectional views of various stages in a method of forming a semiconductor package in accordance with some embodiments.

FIG. 12 to FIG. 14 are schematic cross-sectional views of various semiconductor packages in accordance with some embodiments.

FIG. 15 to FIG. 19 are schematic cross-sectional views of various semiconductor packages in accordance with other embodiments.

FIG. 20 illustrates a method of forming a semiconductor package in accordance with some embodiments.

FIG. 21 illustrates a method of forming a semiconductor package in accordance with some embodiments.

### DETAILED DESCRIPTION

The following disclosure provides many different embodiments, or examples, for implementing different features of the provided subject matter. Specific examples of components and arrangements are described below for the purposes of conveying the present disclosure in a simplified manner. These are, of course, merely examples and are not intended to be limiting. For example, the formation of a second feature over or on a first feature in the description that follows may include embodiments in which the second and first features are formed in direct contact, and may also include embodiments in which additional features may be formed between the second and first features, such that the second and first features may not be in direct contact. In addition, the same reference numerals and/or letters may be used to refer to the same or similar parts in the various examples the present disclosure. The repeated use of the reference numerals is for the purpose of simplicity and clarity and does not in itself dictate a relationship between the various embodiments and/or configurations discussed.

Further, spatially relative terms, such as “beneath”, “below”, “lower”, “on”, “over”, “overlying”, “above”, “upper” and the like, may be used herein to facilitate the description of one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is directed to semiconductor packages and methods of forming the same. In the disclosure, a heat dissipation substrate with high thermal conductivity is provided for a semiconductor package. With the method of the disclosure, the surface roughness is resolved and the heat dissipation substrate provides a planar surface for the subsequent bonding process, so the conventional delamination or cracking issue around the bonding surface is not present. With the heat dissipation substrate of the disclosure, the heat dissipation performance of the semiconductor package is enhanced, and the reliability of the semiconductor package is improved.

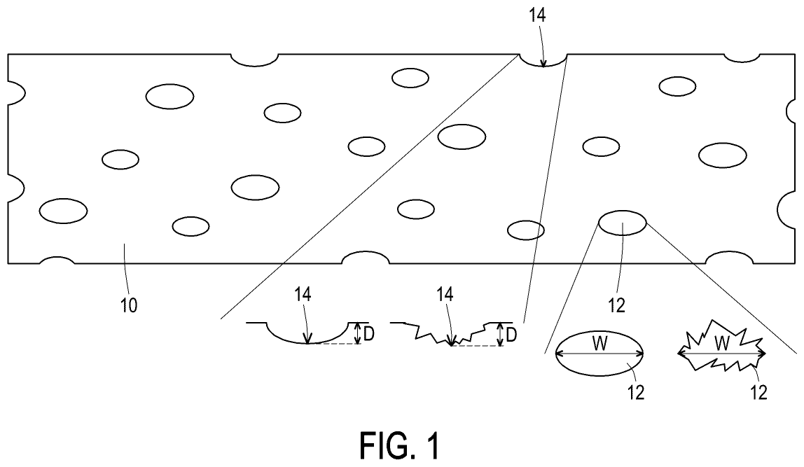

FIG. 1 to FIG. 11 are schematic cross-sectional views of various stages in a method of forming a semiconductor package in accordance with some embodiments. It is understood that the disclosure is not limited by the method described below. Additional operations can be provided before, during, and/or after the method and some of the operations described below can be replaced or eliminated, for additional embodiments of the methods. Although FIG. 1 to FIG. 11 are described in relation to a method, it is appreciated that the structures disclosed in FIG. 1 to FIG. 11 are not limited to such a method, but instead may stand alone as structures independent of the method.

FIG. 1 to FIG. 5 illustrate a method of preparing a heat dissipation substrate with high thermal conductivity and planar bonding surface.

Referring to FIG. 1, a carrier or a substrate 10 is provided. In some embodiments, the substrate 10 is made by a high dissipation material having a thermal conductivity of about 230 W/m·K or more. In some embodiments, the high dissipation material includes SiC, AlN, GaN, a single crystal diamond, the like or a combination thereof. In some embodiments, the substrate 10 is formed by a sintering process, in which raw materials are molded and sintered under the predetermined sintering conditions. Accordingly, the resulting substrate has a porous structure with a rough surface. Specifically, the substrate 10 has pores or voids 12 therein and recesses 14 on the surface thereof. In some embodiments, the pores or voids 12 and the recesses 14 of the substrate 10 have varied sizes (e.g., the maximum dimensions W of respective pores 12 or the maximum depths D of respective recesses 14) ranging from about 0.1 μm to about 5 μm. However, other values and ranges are within the scope of the present disclosure. The pores or voids may have different cross-sectional shapes including a circular-like shape, an oval-like shape, a bar-like shape, a polygon shape, an irregular shape, the like or a combination thereof. Each of the respective voids 12 and recesses 14 may have a smooth surface or an irregular surface, as shown in the enlarged views of FIG. 1. In some embodiments, the porosity of the substrate 10 is less than about 5%, less than 2% or even less. In some embodiments, the substrate 10 has a rough surface with a surface roughness Ra of a few nanometers, such as from about 0.5 nm to about 30 μm, or from about 1 nm to 15 nm. In some embodiments, the surface roughness Ra indicates the average surface roughness for the length of the measurement performed, i.e., the average difference between peaks and valleys within a predetermined sampling length. In some embodiments, the substrate 10 has a rough surface with a surface roughness Rz of a few microns, such as about from 0.1 μm to about 5 μm, or from about 1 μm to about 3 μm. In some embodiments, the surface roughness Rz is calculated by measuring the vertical distance from the highest peak to the lowest valley within a predetermined sampling length or area.

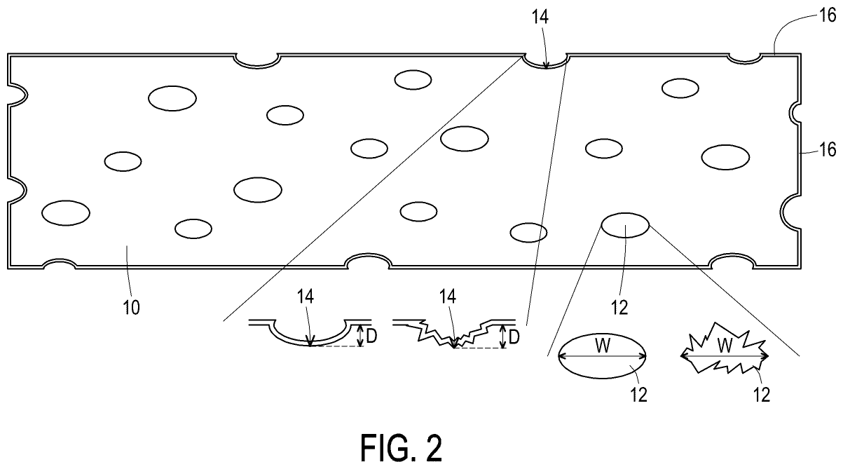

Referring to FIG. 2, a liner layer 16 is formed conformally on the surface of the substrate 10. In some embodiment, the liner layer 16 includes polysilicon, SiOx, SiCx, SiNx, SiOxNy, SiOxCy, SiCxNy or SiOxCyNz, and x, y and z are greater than zero. However, other thermally grown materials or insulating materials are within the scope of the present disclosure. The liner layer 16 is referred to as an “insulating liner” in some examples. In some embodiments, the liner layer 16 is formed by a furnace process, in which multiple substrates 10 are vertically arranged in a furnace chamber, and subjected to a thermal growing process. Accordingly, the resulting liner layer 16 is formed conformally on the entire surface of each substrate 10. Specifically, the porous top surface, the porous side surface and the porous bottom surface are lined with the liner layer 16. In some embodiments, the liner layer 16 has a thickness ranging from about 10 angstroms to about 1 μm, such as from about 25 angstroms to about 1000 angstroms. However, other values and ranges are within the scope of the present disclosure. In some embodiments, the liner layer 16 lines the surfaces of the recesses 14 but does not completely fill all of the recesses 14. Specifically, due to the varied sizes of the recesses 14, some of the shallower or narrower recesses 14 are completely filled by the liner layer 16, while some of the deeper or wider recesses 14 are not completely filled by the liner layer 16.

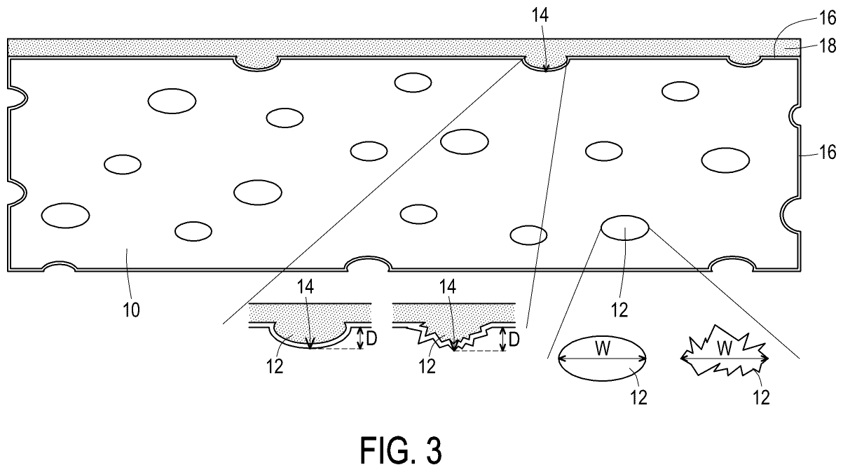

Referring to FIG. 3, a filling layer 18 is formed over the substrate 10, filling the recesses 14. In some embodiment, the filling layer 18 includes SiOx, SiNx or SiOxNy, the like or a combination thereof, and x and y are greater than zero. However, other thermally deposited materials or insulating materials are within the scope of the present disclosure. The filling layer 18 is referred to as an “insulating filling layer” in some examples. In some embodiments, the filling layer 18 is formed by a deposition process, such as chemical vapor deposition (CVD), atomic layer deposition (ALD) or the like, in which the substrate 10 is placed horizontally on a platen in a deposition chamber, and subjected to a material deposition. Accordingly, the resulting filling layer 18 is formed on the liner layer 18 on the top surface of the substrate 10. Specifically, the filling layer 18 is formed on the top surface of the substrate 10 and completely fills the recesses 14 at the top surface of the substrate 10. In some embodiments, the filling layer 18 has a thickness ranging from about 0.1 μm to about 15 μm, such as from about 1 μm to about 10 μm. However, other values and ranges are within the scope of the present disclosure.

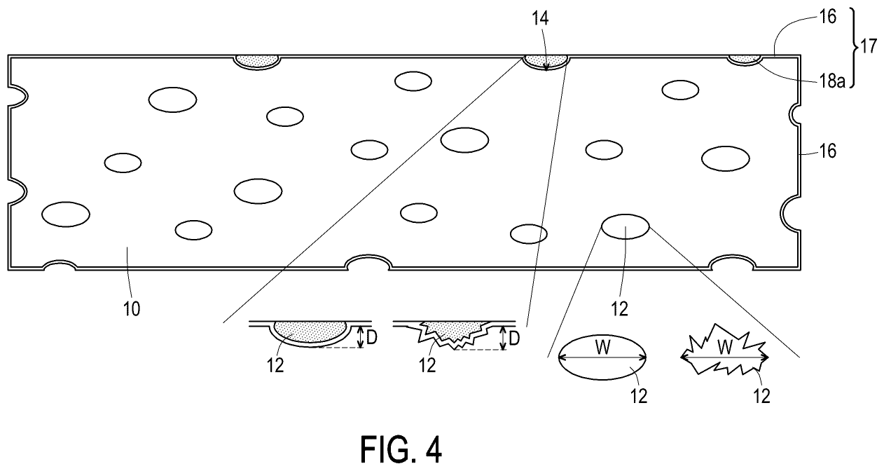

Referring to FIG. 4, the excess portion of the filling layer 18 outside of the recesses 14 are removed. In some embodiments, a polishing process (e.g., chemical mechanical polishing process) is performed to the filling layer 18, using the liner layer 16 as a polish stop layer, until the surface of the liner layer 16 is exposed. After the polishing process, the top surface of the remaining filling layer 18a in the recesses 14 is substantially coplanar with or flush with the top surface of the adjacent liner layer 16.

In some examples, the liner layer 16 and the filling layer 18a at the top surface of the substrate 10 are collectively referred to as a buffer layer 17, in which the liner layer 16 is continuously disposed across the top surface the substrate 10, and the filling layer 18a is discontinuously disposed across the top surface the substrate 10. Specifically, the filling layer 18a is disposed in the recesses 14 at the top surface of the substrate 10. In the disclosure, the buffer layer 17 is configured to provide a planar surface for the subsequent bonding process, so the conventional delamination or cracking issue around the bonding surface is not present.

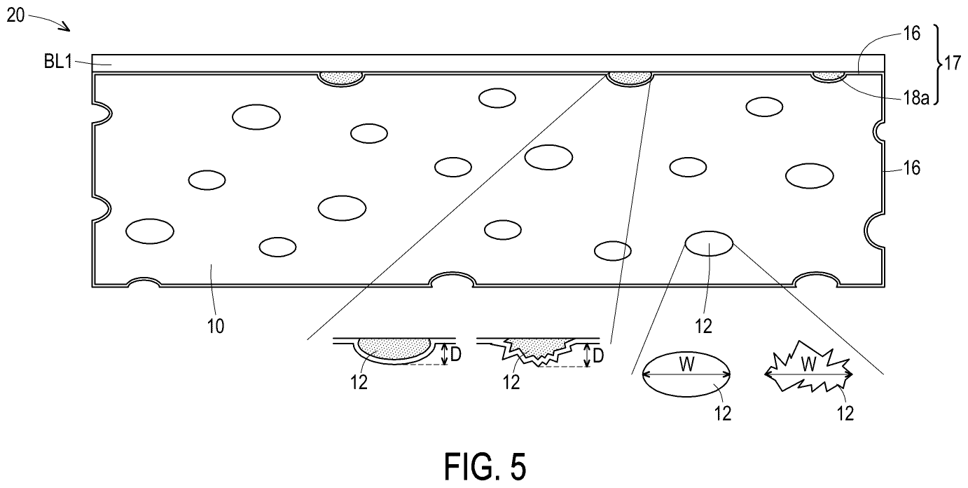

Referring to FIG. 5, a bonding layer BL1 is formed on the substrate 10, covering the liner layer 16 and the filling layer 18a. In some embodiments, the bonding layer BL1 is in contact with the liner layer 16 and the filling layer 18a. In some embodiment, the bonding layer BL1 includes silicon (Si), silicon oxide (SiOx, where x>0), silicon nitride (SiNx, where x>0), silicon oxynitride (SiOxNy, where x>0 and y>0) or other suitable bonding materials. In some embodiments, the bonding layer BL1 is formed by a deposition process (e.g., CVD, ALD or the like) followed by a planarization process. In some embodiments, the filling layer 18a and the bonding layer BL1 include the same material, so the interface between the filling layer 18a and the bonding layer BL1 is invisible. In other embodiments, the filling layer 18a and the bonding layer BL1 include different materials, so the interface is present between the filling layer 18a and the bonding layer BL1. In some embodiments, the bonding layer BL1 has a flat surface with a surface roughness Ra of less than about 0.5 nm, less than about 0.3 nm or even less.

In some embodiments, the substrate 10, the buffer layer 17 (including the liner layer 16 and the filling layer 18a) and the bonding layer BL1 constitute a heat dissipation substrate 20 of the disclosure. In some embodiments, the heat dissipation substrate 20 has a thickness of about 500 μm to about 1000 μm, such as about 600 μm to about 800 μm. Other values and ranges are within the scope of the present disclosure. As compared to the conventional silicon heat dissipation substrate having a thermal conductivity of about 140 W/m. K, the heat dissipation substrate 20 of the disclosure having a thermal conductivity of about 230 W/m·K or more is beneficial for heat dissipation. The heat dissipation substrate 20 is referred to as a “heat dissipation carrier” or “heat dissipation support” in some examples. Besides, the heat dissipation substrate 20 of the disclosure provides a planar bonding surface, so the conventional delamination or cracking issue around the bonding surface is not present.

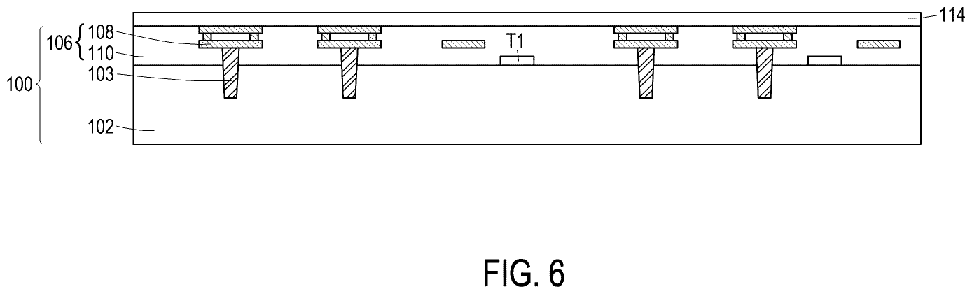

Referring to FIG. 6, at least one semiconductor die 100 is provided. The semiconductor die 100 may be any suitable type of die, such as a logic die, a memory die, a radio frequency die, an analog chip, a sensor chip, a power management die, a voltage regulator chip, a micro-electro-mechanical-system (MEMS) die, a system on chip (SoC), a CPU, a GPU, an xPU, or the like.

In some embodiments, the semiconductor die 100 includes an active side (e.g., front side) and a non-active side (e.g., back side) opposite to the active side. Throughout the description, the side of the semiconductor die 100 with transistors or devices is referred to as an active side. In some embodiments, the semiconductor die 100 includes semiconductor substrate 102, at least one device T1 and an interconnect structure 106.

The semiconductor substrate 102 may include an elementary semiconductor such as silicon, germanium and/or a compound semiconductor such as silicon germanium, silicon carbide, gallium arsenic, indium arsenide, gallium nitride or indium phosphide. In some embodiments, the semiconductor substrate 102 may take the form of a planar substrate, a substrate with multiple fins, nanowires, or other forms. The semiconductor die 100 may further include through substrate vias (TSVs) 103 formed in the semiconductor substrate 102 and electrically connected to interconnect wirings or lines of the interconnect structure 106. As illustrated in FIG. 6, the through substrate vias 103 are embedded in the semiconductor substrate 102 and the interconnect structure 106, and the through substrate vias 103 are not revealed from the back side of the semiconductor substrate 102 at this stage. The through substrate vias 103 may include Cu, Ti, Ta, W, Ru, Co, Ni, the like, an alloy thereof, or a combination thereof. In some embodiments, the through substrate vias 103 are formed by an electroplating process and include one or more conductive layers, and insulated from the semiconductor substrate 102 by insulating liners.

The device T1 is disposed on/in the semiconductor substrate 102 and includes one or more functional devices. The functional devices may include active components, passive components, or a combination thereof. In some embodiments, the functional devices may include integrated circuits devices. The functional devices are, for example, transistors, capacitors, resistors, diodes, photodiodes, fuse devices and/or other similar devices. In some embodiments, the semiconductor die 100 is referred to as a “first device die”, “first-tier semiconductor die”, or “lower integrated circuit structure”.

The interconnect structure 106 is formed on the semiconductor substrate 102 and electrically connected to the device T1. The interconnect structure 106 may include one or more dielectric layers, collectively referred to as a dielectric layer 110, and metal features 108 embedded by the dielectric layer 110. Herein, only two layers of the metal features 108 are illustrated; however, the number of layers of metal features 108 are not limited by the disclosure. Multiple layers of the metal features 108 are within the scope of the present disclosure.

The metal features 108 are disposed in the dielectric layer 110 and electrically connected with each other. In some embodiments, the dielectric layer 110 may include etch stop materials and inter-metal dielectric (IMD) materials with different materials. The etch stop materials may include silicon nitride, silicon oxynitride, silicon carbide, metal oxide such as Al₂O₃, the like, or a combination thereof. The IMD materials may include silicon oxide, silicon oxynitride, silicon nitride, a low-k material having a dielectric constant less than 3.5, the like, or a combination thereof. The metal features 108 include metal lines, metal vias and/or metal pads electrically connected to each other. The metal vias are formed between and in direct contact with two metal lines. The metal features 108 may include Cu, Al, Ti, Ta, W, Ru, Co, Ni, the like, or a combination thereof. In some embodiments, a seed layer and/or a barrier layer may be disposed between each metal feature 108 and the dielectric layer 110. The seed layer may include Ti/Cu. The barrier layer may include Ta, TaN, Ti, TiN, CoW, the like, or a combination thereof. In some embodiments, the interconnect structure 106 is formed by a dual damascene process. In other embodiments, the interconnect structure 106 is formed by multiple single damascene processes. In other embodiments, the interconnect structure 106 is formed by an electroplating process.

In some embodiments, a bonding film 114 is further provided on top of the interconnect structure 106. In some embodiment, the bonding film 114 includes silicon (Si), silicon oxide (SiOx, where x>0), silicon nitride (SiNx, where x>0), silicon oxynitride (SiOxNy, where x>0 and y>0) or other suitable bonding materials. In some embodiments, the bonding film 114 is formed by a deposition process (e.g., CVD, ALD or the like) followed by a planarization process.

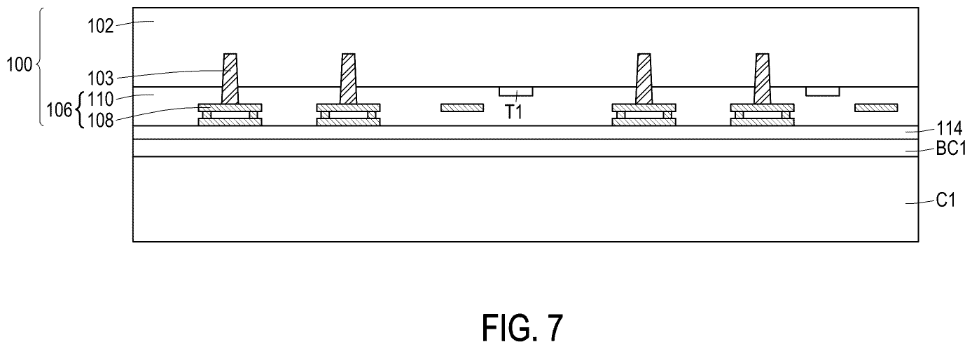

Referring to FIG. 7, a carrier C1 including a bonding film BC1 thereon is provided. The carrier C1 may be a semiconductor wafer such as a silicon wafer, and the bonding film BC1 may be a bonding layer prepared for fusion bond. In some embodiments, the bonding film BC1 is a deposited layer formed over the top surface of the carrier C1. In other embodiments, the bonding film BC1 is a portion of the carrier C1 for fusion bond. In some embodiments, the bonding film BC1 includes silicon (Si), silicon oxide (SiOx, where x>0), silicon nitride (SiNx, where x>0), silicon oxynitride (SiOxNy, where x>0 and y>0) or other suitable bonding materials.

The semiconductor die 100 is turned over and bonded to the carrier C1. In some embodiments, the semiconductor die 100 is picked and placed on the carrier C1, with the front side of the semiconductor die 100 facing the bonding film BC1 of the carrier C1, so the bonding film 114 is in contact with the bonding film BC1. The bonding between the bonding film BC1 and the bonding film 114 is referred to as a “fusion bonding”. In some embodiments, the bonding film BC1 and the bonding film 114 include the same material such as silicon oxide. In other embodiments, the bonding film BC1 and the bonding film 114 include different materials.

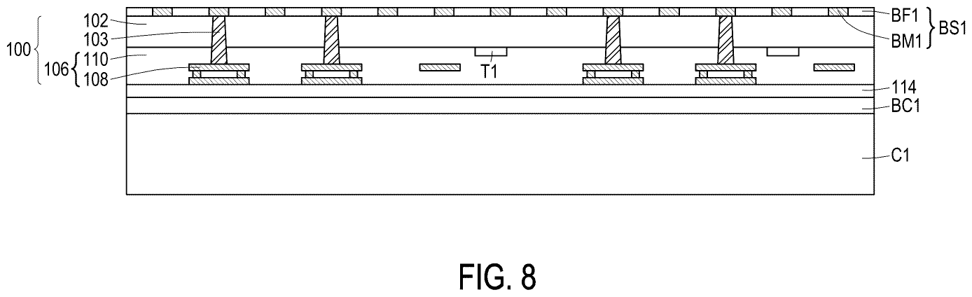

Referring to FIG. 8, a removing process is performed to the semiconductor die 100, until the through substrate vias 103 are exposed. Specifically, the removing process is performed to the back side of the semiconductor die 100, so as to reduce the thickness of the semiconductor substrate 102. In some embodiments, the removing process includes a mechanical grinding process, a chemical mechanical polishing (CMP) process, or a combination thereof.

Thereafter, a bonding structure BS1 is formed over the back side of the semiconductor die 100 and electrically connected to the through substrate vias 103. In some embodiments, the bonding structure BS1 is regarded as part of the semiconductor die 100.

In some embodiments, the bonding structure BS1 includes at least one bonding film BF1 and bonding metal features BM1 embedded in the bonding film BF1. In some embodiments, the bonding film BF1 includes an insulating material, a dielectric material, a polymer material or a combination thereof. For example, the bonding film BF1 includes silicon (Si), silicon oxide (SiOx, where x>0), silicon nitride (SiNx, where x>0), silicon oxynitride (SiOxNy, where x>0 and y>0) or other suitable bonding materials. The bonding metal features BM1 may include Cu, Ti, Ta, W, Ru, Co, Ni, an alloy thereof, the like, or a combination thereof. In some embodiments, a seed layer and/or a barrier layer may be disposed between each bonding metal feature BM1 and the bonding film BF1. The seed layer may include Ti/Cu. The barrier layer may include Ta, TaN, Ti, TiN, CoW or a combination thereof. In some embodiments, some of the bonding metal features BM1 are active pads configured to bond to and electrically connect to the overlying semiconductor dies or die stacks, and some of the bonding metal features BM1 are dummy pads configured to eliminate the process variation between the bond area and non-bond area.

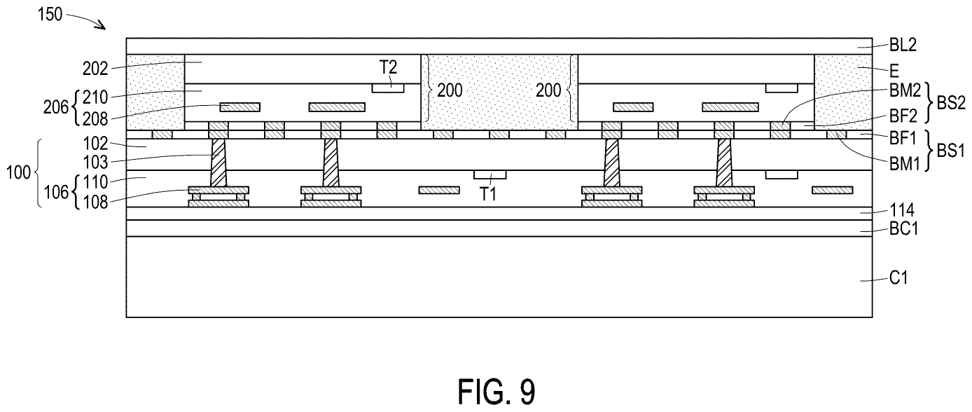

Referring to FIG. 9, multiple semiconductor dies 200 (e.g., memory dies, logic dies or other suitable dies) are provided and placed on the semiconductor die 100. In FIG. 9, two semiconductor dies 200 are illustrated; however, the number of the semiconductor dies 200 is not limited by the disclosure. In some embodiments, the semiconductor dies 200 may have similar functions and/or widths, but the disclosure is not limited thereto. In other embodiments, the semiconductor dies 200 may have different functions and/or widths.

In some embodiments, each of the semiconductor dies 200 includes an active side (e.g., front side) and a non-active side (e.g., back side) opposite to the active side. Throughout the description, the side of the semiconductor die 200 with transistors or devices is referred to as an active side. In some embodiments, each of the semiconductor dies 200 includes a semiconductor substrate 202, at least one device T2 and an interconnect structure 206.

The semiconductor substrate 202 may include an elementary semiconductor such as silicon, germanium and/or a compound semiconductor such as silicon germanium, silicon carbide, gallium arsenic, indium arsenide, gallium nitride or indium phosphide. In some embodiments, the semiconductor substrate 202 may take the form of a planar substrate, a substrate with multiple fins, nanowires, or other forms known to people having ordinary skill in the art. If needed, the semiconductor die 200 may further include through substrate vias (TSVs) (not shown) formed in the semiconductor substrate 202 and electrically connected to interconnect wirings or lines of the interconnect structure 206.

The device T2 is disposed on/in the semiconductor substrate 202 and includes one or more functional devices. The functional devices may include active components, passive components, or a combination thereof. In some embodiments, the functional devices may include integrated circuits devices. The functional devices are, for example, transistors, capacitors, resistors, diodes, photodiodes, fuse devices and/or other similar devices. In some embodiments, the semiconductor die 200 is referred to as a “second device die”, “second-tier semiconductor die”, or “upper integrated circuit structure”. In some embodiments, the semiconductor die 200 may be replaced by a die stack including multiple dies vertically stacked on each other.

The interconnect structure 206 is formed on the semiconductor substrate 202 and electrically connected to the device T2. The interconnect structure 206 may include one or more dielectric layers, collectively referred to as a dielectric layer 210, and metal features 208 embedded by the dielectric layer 210. In some embodiments, the dielectric layer 210 may include etch stop materials and inter-metal dielectric (IMD) materials with different materials. The etch stop materials may include silicon nitride, silicon oxynitride, silicon carbide, metal oxide such as Al₂O₃, the like, or a combination thereof. The IMD materials may include silicon oxide, silicon oxynitride, silicon nitride, a low-k material having a dielectric constant less than 3.5, the like, or a combination thereof. The metal features 208 include metal lines, metal vias and/or metal pads electrically connected to each other. The metal vias are formed between and in direct contact with two metal lines. The metal features 208 may include Cu, Al, Ti, Ta, W, Ru, Co, Ni, the like, or a combination thereof. In some embodiments, a seed layer and/or a barrier layer may be disposed between each metal feature 208 and the dielectric layer 210. The seed layer may include Ti/Cu. The barrier layer may include Ta, TaN, Ti, TiN, CoW, the like, or a combination thereof. In some embodiments, the interconnect structure 206 is formed by a dual damascene process. In other embodiments, the interconnect structure 206 is formed by multiple single damascene processes. In other embodiments, the interconnect structure 206 is formed by an electroplating process.

In some embodiments, a bonding structure BS2 is further provided over the interconnect structure 206 of each semiconductor die 200. In some embodiments, the bonding structure BS2 is regarded as part of the semiconductor die 200.

In some embodiments, the bonding structure BS2 includes at least one bonding film BF2 and bonding metal features BM2 embedded in the bonding film BF2. In some embodiments, the bonding film BF2 includes an insulating material, a dielectric material, a polymer material or a combination thereof. For example, the bonding film BF2 includes silicon (Si), silicon oxide (SiOx, where x>0), silicon nitride (SiNx, where x>0), silicon oxynitride (SiOxNy, where x>0 and y>0) or other suitable bonding materials. The bonding metal features BM2 may include Cu, Ti, Ta, W, Ru, Co, Ni, an alloy thereof, the like, or a combination thereof. In some embodiments, a seed layer and/or a barrier layer may be disposed between each bonding metal feature BM2 and the bonding film BF2. The seed layer may include Ti/Cu. The barrier layer may include Ta, TaN, Ti, TiN, CoW, the like, or a combination thereof.

As shown in FIG. 9, the bonding structures BS2 of the semiconductor dies 200 are aligned with the bonding structure BS1 of the semiconductor die 100, and a bonding including a metal-to-metal bonding and a dielectric-to-dielectric bonding is performed, such that the bonding structures BS2 are hybrid bonded to the bonding structure BS1. Specifically, the bonding metal features BM2 are connected to the bonding metal features BM1, and the bonding dielectric film BF2 is connected to the bonding dielectric film BF1. In some embodiments, the semiconductor dies 200 and the semiconductor die 100 are bonded through a face-to-back bonding process including a metal-to-metal bonding and a dielectric-to-dielectric bonding. However, the disclosure is not limited thereto. In other embodiments, the semiconductor dies 200 and the semiconductor die 100 may be bonded through a face-to-face bonding process including a metal-to-metal bonding and a dielectric-to-dielectric bonding, or a back-to-back bonding process including a metal-to-metal bonding and a dielectric-to-dielectric bonding.

Thereafter, an encapsulation layer E is formed to cover the semiconductor die 100 and around the semiconductor dies 200. In some embodiments, the encapsulation layer E includes a molding compound, a molding underfill, a resin or the like. In some embodiments, the encapsulation layer E includes a polymer material (such as polybenzoxazole (PBO), polyimide, benzocyclobutene (BCB), the like, or a combination thereof), an insulating material (such as silicon oxide, silicon nitride, the like, or a combination thereof), or a combination thereof. In some embodiments, the encapsulation layer E is formed by an over-molding process followed by a planarization process. Accordingly, the surface of the encapsulation layer E is flush with surfaces the semiconductor substrates 202 of the semiconductor dies 200.

In some embodiments, a bonding layer BL2 is further provided over the encapsulation layer E and the semiconductor dies 200. In some embodiments, the bonding layer BL2 is in contact with the encapsulation layer E and the semiconductor substrates 202 of the semiconductor dies 200. In some embodiment, the bonding layer BL2 includes silicon (Si), silicon oxide (SiOx, where x>0), silicon nitride (SiNx, where x>0), silicon oxynitride (SiOxNy, where x>0 and y>0) or other suitable bonding materials. In some embodiments, the bonding layer BL2 is formed by a deposition process (e.g., CVD, ALD or the like) followed by a planarization process.

In some embodiments, the semiconductor die 100, the semiconductor dies 200, the encapsulation layer E and the bonding layer BL2 constitute an integrated circuit structure 150.

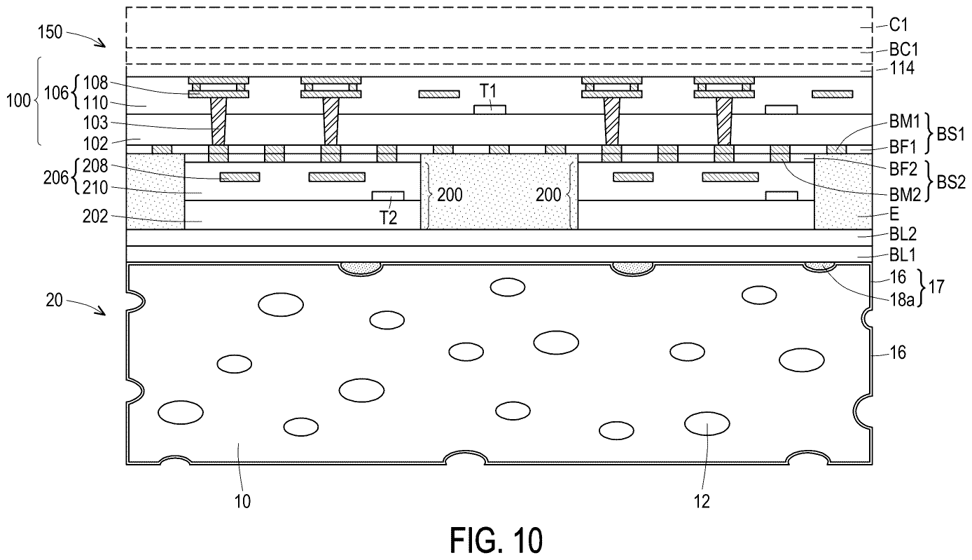

Referring to FIG. 10, the heat dissipation substrate 20 of FIG. 5 is bonded to the integrated circuit structure 150 of FIG. 9. In some embodiments, the integrated circuit structure 150 is turned over and placed on the heat dissipation substrate 20, such that the bonding layer BL2 of the integrated circuit structure 150 is in contact with the bonding layer BL1 or the heat dissipation substrate 20. The bonding between the bonding layer BL1 and the bonding layer BL2 is referred to as a “fusion bonding”.

Thereafter, the carrier C1 is debonded from the structure. In one embodiment, the debonding process is a laser debonding process or a suitable process. The bonding film BC1 and the bonding film 114 are further removed during the debonding process. In some embodiments, the removing process is an etching process and/or a cleaning process.

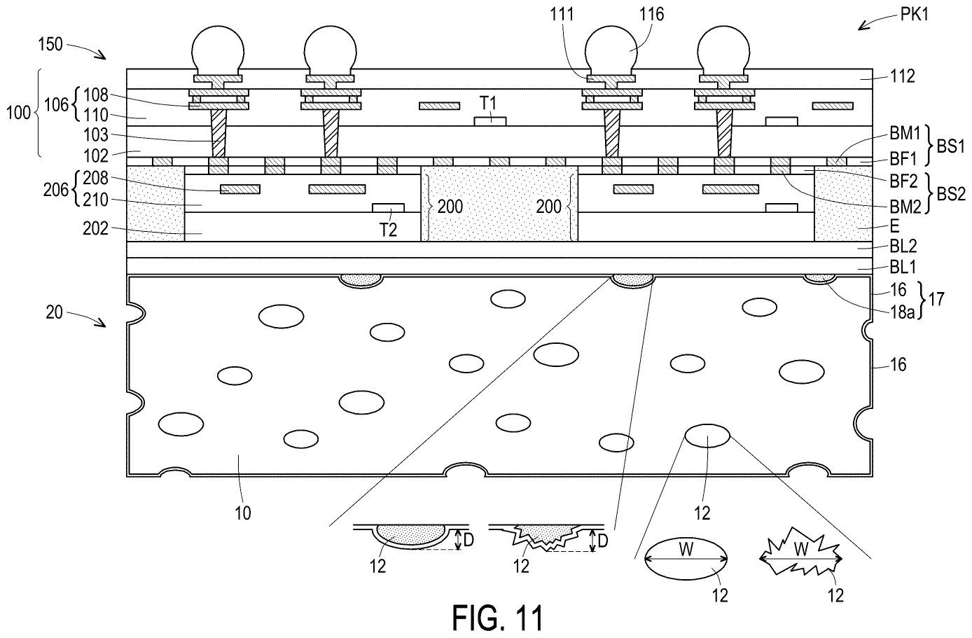

Referring to FIG. 11, die pads 111 are formed over and electrically connected to the interconnect structure 106 of the semiconductor die 100. In some embodiments, the die pads 111 are in physical contact with the topmost metal features 108 of the interconnect structure 106. In some embodiments, the die pads 111 are aluminum pads. However, the disclosure is not limited thereto. In other embodiments, the dies pads 111 are copper pads, nickel pads or pads made by other suitable materials. Each of the die pads 111 may be a single layer or a multiple-layer structure.

The passivation layer 112 is formed over the interconnect structure 106 and covers the sidewalls and top surfaces of the die pads 111. In some embodiments, the passivation layer 112 includes silicon oxide, silicon nitride, benzocyclobutene (BCB) polymer, polyimide (PI), polybenzoxazole (PBO) the like, or a combination thereof, and is formed by a suitable process such as spin coating, CVD or the like.

Thereafter, conductive terminals or bumps 116 are formed through the passivation layer 112 and electrically connected to the die pads 111 of the semiconductor die 100. In some embodiments, the bumps 116 are disposed within a chip region and in physical contact with the die pads 111. In some embodiments, the bumps 116 include solder bumps, and/or may include metal pillars (e.g., copper pillars), solder caps formed on metal pillars, and/or the like. The bumps 116 may be formed by a suitable process such as evaporation, electroplating, ball drop, or screen printing. A semiconductor package PK1 of the disclosure is thus completed.

In the semiconductor package PK1, a heat dissipation substrate 20 with high thermal conductivity is bonded to an integrated circuit structure 150, so the heat dissipation performance of the semiconductor package is enhanced. Besides, the heat dissipation substrate 20 of the disclosure provides a planar surface for bonding to the integrated circuit structure 150, so the conventional delamination or cracking issue around the bonding surface is not present. Accordingly, the reliability of the semiconductor package is improved.

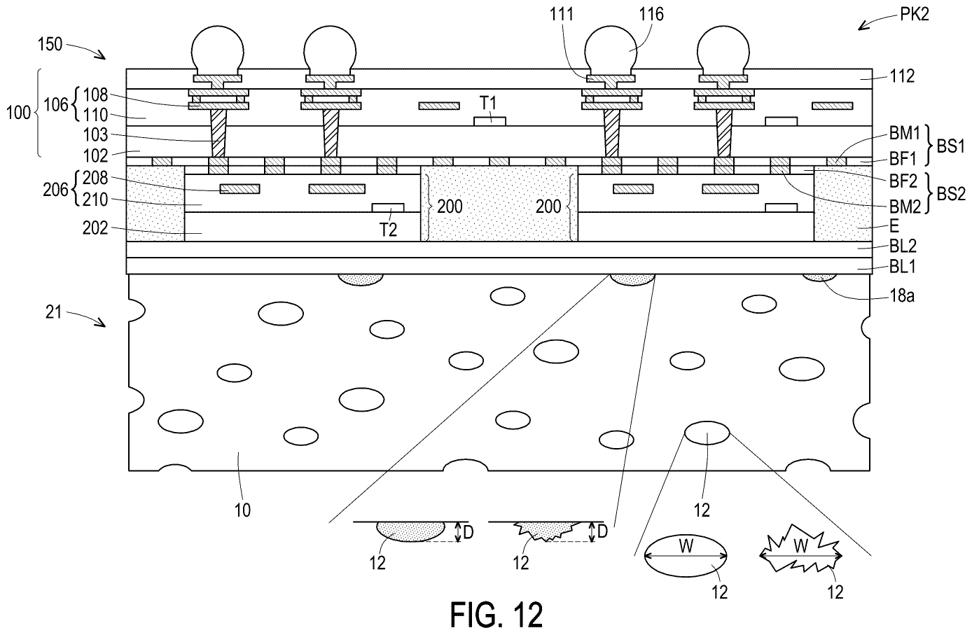

FIG. 12 illustrates a semiconductor package in accordance with some embodiments. The forming method of the semiconductor package PK2 of FIG. 12 is similar to the forming method of the semiconductor package PK1 described in FIG. 1 to FIG. 11, and the difference between them lies in that, the formation of the liner layer 16 is omitted from FIG. 12, so the resulting heat dissipation substrate 21 of semiconductor package PK2 is free of the liner layer 16.

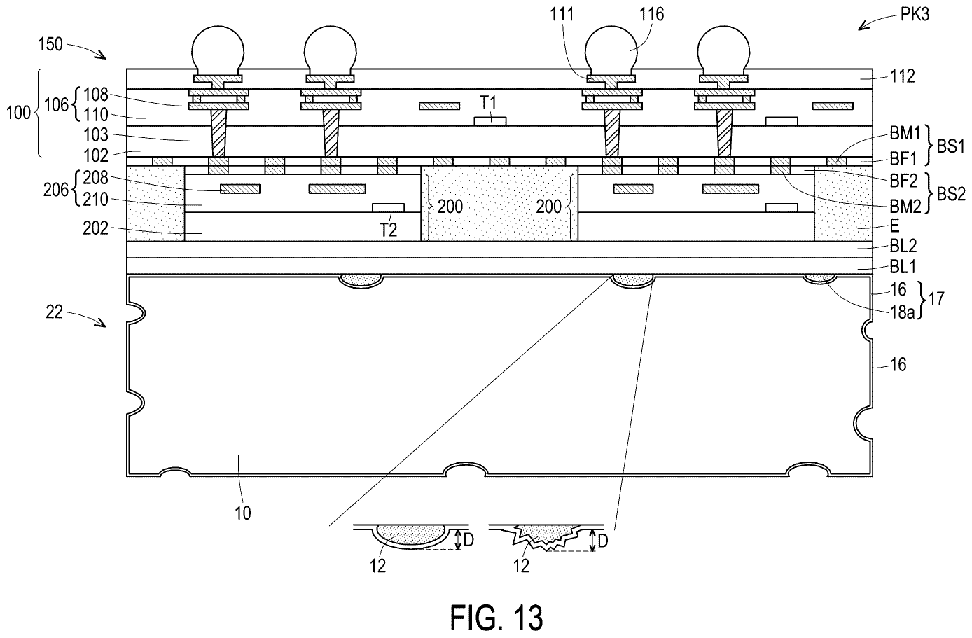

FIG. 13 illustrates a semiconductor package in accordance with some embodiments. The forming method of the semiconductor package PK3 of FIG. 13 is similar to the forming method of the semiconductor package PK1 described in FIG. 1 to FIG. 11, and the difference between them lies in the forming method of the substrate 10. Specifically, the substrate 10 of the heat dissipation substrate 20 is a porous structure because it is formed by a sintering process. However, the substrate 10 of the heat dissipation substrate 22 is formed by a deposition process such as CVD, so the substrate 10 is formed as a void-free substrate with a rough surface. The porosity of the porosity of the substrate 10 of the heat dissipation substrate 22 is about zero or less than about 0.5%. Besides, the substrate 10 of the heat dissipation substrate 22 has a rough surface with a surface roughness Ra of a few nanometers, such as from about 0.5 nm to about 30 μm, or from about 1 nm to 15 nm. In some embodiments, the substrate 10 of the heat dissipation substrate 22 has a rough surface with a surface roughness Rz of a few microns, such as about from 0.1 μm to about 5 μm, or from about 1 μm to about 3 μm.

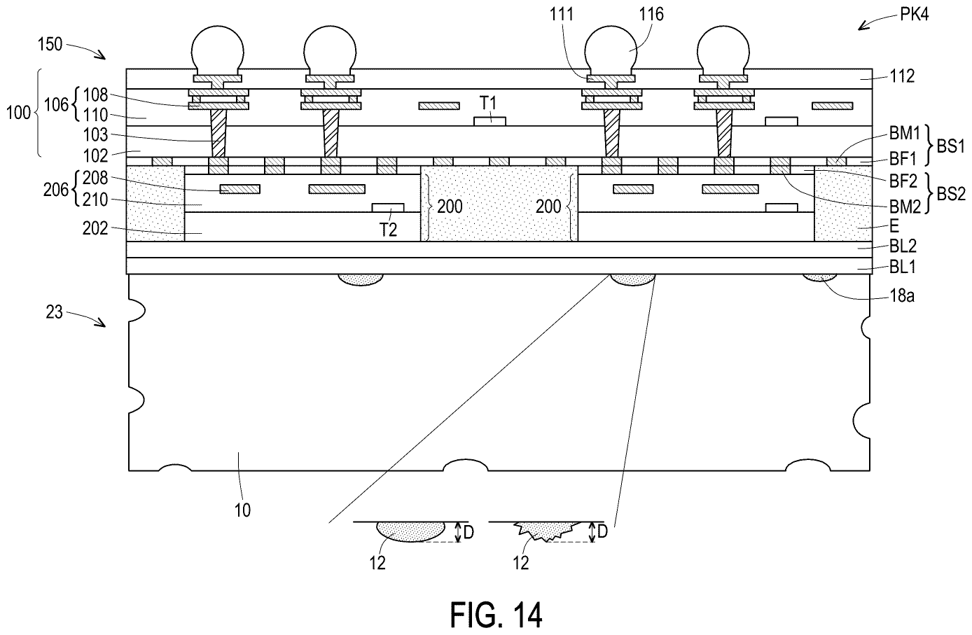

FIG. 14 illustrates a semiconductor package in accordance with some embodiments. The semiconductor package PK4 of FIG. 14 is similar to the semiconductor package PK3 of FIG. 13, and the difference between them lies in that, the formation of the liner layer 16 is omitted from FIG. 14, so the resulting heat dissipation substrate 23 of semiconductor package PK4 is free of the liner layer 16.

The above-mentioned semiconductor packages may stand alone as structures or in combination with other integrated circuit structures or packages.

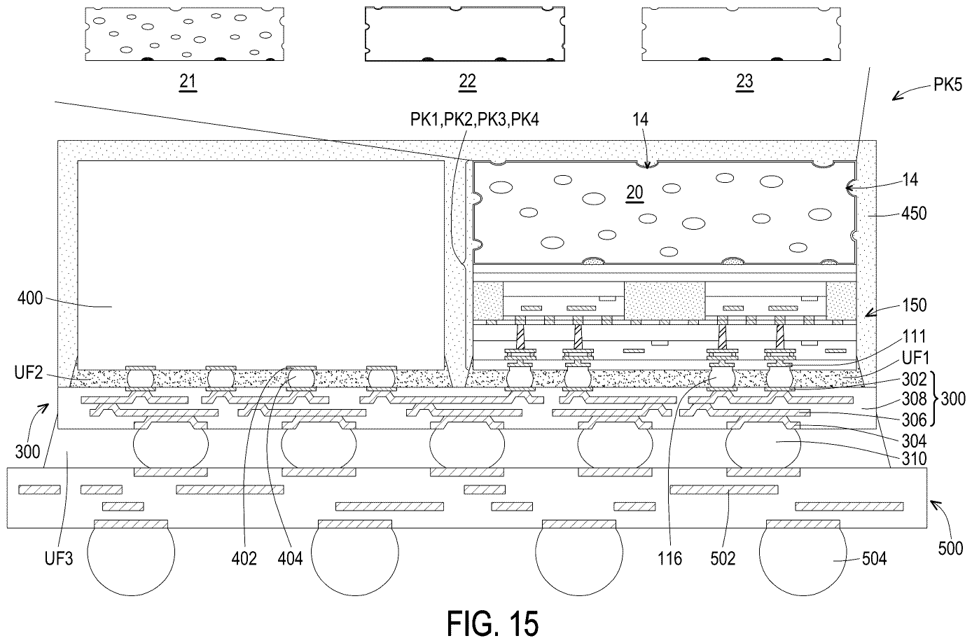

FIG. 15 illustrates a semiconductor package in accordance with some embodiments. The semiconductor package of FIG. 15 is a chip-on-wafer-on-substrate package structure, for example, including chips disposed on an interposer wafer, and the interposer wafer disposed on a board substrate.

Referring to FIG. 15, an interposer structure 300 is provided. In some embodiments, the interposer structure 300 includes interposer wirings 306 embedded in an interposer substrate 306. In some embodiments, the interposer structure 300 is referred to as a “silicon interposer structure” when the interposer substrate 306 includes a semiconductor material, such as silicon and/or a compound semiconductor such as silicon germanium or silicon carbide. In other embodiments, the interposer structure 300 is referred to as an “organic interposer structure” when interposer substrate 306 includes an organic material, such as polybenzoxazole (PBO), polyimide (PI), benzocyclobutene (BCB), the like, or a combination thereof. The organic material of the interposer 201 may be replaced by a dielectric material or an insulating material as needed.

The interposer wirings 306 include metal lines and/or metal vias electrically connected each other. In some embodiments, each interposer wiring 306 includes Cu, Al, Ti, Ta, W, Ru, Co, Ni, the like, or a combination thereof. In some embodiments, a seed layer and/or a barrier layer may be disposed between each interposer wiring 306 and the adjacent interposer substrate 306. The seed layer may include Ti/Cu. The barrier layer may include Ta, TaN, Ti, TiN, CoW or a combination thereof.

The interposer structure 300 further includes metal pads 302 configured to electrically connected to the overlying electrical component, semiconductor devices or integrated circuit structure, and metal pads 304 configured to electrically connected to the conductive terminals.

In some embodiments, the interposer structure 300 is an active interposer that contains at least one functional device or integrated circuit device included in the surface portion of the interposer substrate 306. Such active interposer is referred to as a “device-containing interposer” in some examples. In some embodiments, the functional device includes an active device, a passive device, or a combination thereof. The functional device includes, for example but not limited to, transistors, capacitors, resistors, diodes, photodiodes, fuse devices and/or other similar components. In other embodiments, the interposer structure 300 is a passive interposer, which is lack of a functional device or integrated circuit device. Such passive interposer is referred to as a “device-free interposer” in some examples.

Still referring to FIG. 15, an integrated circuit structure 400 is provided and bonded to the interposer structure 300. The integrated circuit structure 400 may be a system device such as application-specific integrated circuit (ASIC), a field programmable gate array (FPGA), a central processing unit (CPU) die, a graphics processing unit (GPU) die, an artificial intelligence (AI) engine die, a transceiver (TRX) die, or the like. In some embodiments, the integrated circuit structure 400 includes a substrate and a device layer. The substrate may include elementary semiconductor such as silicon, germanium and/or a compound semiconductor such as silicon germanium, silicon carbide, gallium arsenic, indium arsenide, gallium nitride or indium phosphide. The substrate may be doped as needed. The device layer may include a transistor such as a fin field effect transistor (FinFET), a nanostructure FET (nano-FET) (e.g., a nanosheet transistor, a nanowire transistor or a gate-all-around transistor), a planar FET, the like, or a combination thereof. The device layer may further include an interconnect structure electrically connected to the transistor.

In some embodiments, the integrated circuit structure 400 further includes metal pads 402 configured to electrically connected to the underlying electrical component, semiconductor devices or integrated circuit structure. Specifically, the integrated circuit structure 400 is bonded to the interposer structure 300 through the metal pads 402, bumps 404 and the metal pads 302. The bumps 404 may be formed over the metal pads 402, the metal pads 302 or both. In some embodiments, the bumps 404 include solder bumps, and/or may include metal pillars (e.g., copper pillars), solder caps formed on metal pillars, and/or the like. The bumps 404 may be formed by a suitable process such as evaporation, electroplating, ball drop, or screen printing.

Still referring to FIG. 15, a semiconductor package PK1 with a heat dissipation substrate 20 (as shown in FIG. 11) is provided and bonded to the interposer structure 300. In some embodiments, the semiconductor package PK1 is placed on the interposer structure 300 with the heat dissipation substrate 20 facing up. Specifically, the semiconductor package PK1 is bonded to the interposer structure 300 through the die pads 111, the bumps 116 and the metal pads 302. The semiconductor package PK1 with the heat dissipation substrate 20 may be replaced by a semiconductor package PK2 with a heat dissipation substrate 21 (as shown in FIG. 12), a semiconductor package PK3 with a heat dissipation substrate 23 (as shown in FIG. 13) or a semiconductor package PK4 with a heat dissipation substrate 24 (as shown in FIG. 14) in other embodiments.

In some embodiments, after the integrated circuit structure 400 and the semiconductor package PK1 are bonded to the interposer structure 300, an underfill layer UF1 is formed to fill the space between the integrated circuit structure 400 and the interposer structure 300 around the bumps 404, and an underfill layer UF2 is formed to fill the space between semiconductor package PK1 and the interposer structure 300 around the bumps 116. In some embodiments, each of the underfill layer UF1 and UF2 includes a molding compound such as epoxy, and is formed using dispensing, injecting, and/or spraying process. At least one of the underfill layers UF1 and UF2 may be omitted in some examples.

Thereafter, an encapsulation layer 450 is formed over the interposer structure 300 and around the integrated circuit structure 400 and the semiconductor package PK1. In some embodiments, the encapsulation layer 450 includes a molding compound, a molding underfill, a resin or the like. In some embodiments, the encapsulation layer 450 includes a polymer material (such as polybenzoxazole (PBO), polyimide, benzocyclobutene (BCB), the like, or a combination thereof), an insulating material (such as silicon oxide, silicon nitride, the like, or a combination thereof), or a combination thereof. In some embodiments, the encapsulation layer 450 is formed by an over-molding process, and the encapsulation layer 450 encapsulates sidewalls and tops of the integrated circuit structure 400 and the semiconductor package PK1 and fills in the recesses 14 at the exposed surfaces of the heat dissipation substrate 21. In some embodiments, a planarization process is optionally performed after the over-molding process, so the recesses 14 at the side of the heat dissipation substrate 21 opposite to the bonding side are exposed to the external environment.

In some embodiments, a board substrate 500 is provided below and electrically connected to the interposer structure 300. In some embodiments, the board substrate 500 is bonded to the interposer structure 300 through the bumps 310. In some embodiments, the bumps 310 include solder bumps, and/or may include metal pillars (e.g., copper pillars), solder caps formed on metal pillars, and/or the like. The bumps 404 may be formed by a suitable process such as evaporation, electroplating, ball drop, or screen printing.

In some embodiments, the board substrate 500 includes a core layer and two build-up layers on opposite sides of the core layer. In some embodiments, the board substrate 500 includes wiring patterns 502 that penetrate through the core layer and the build-up layers for providing electrical routing between different devices and electric components. The wiring patterns 502 include lines, vias, pads and/or connectors. The board substrate 500 is referred to as a “printed circuit board (PCB)” in some examples. In other embodiments, the core layer of the board substrate 500 may be omitted as needed, and such board substrate 500 is referred to as a “coreless board substrate”.

Thereafter, an underfill layer UF3 is formed to fill the space between the interposer structure 300 and the board substrate 500, and surrounds the bumps 310. In some embodiments, the underfill layer UF3 includes a molding compound such as epoxy, and is formed using dispensing, injecting, and/or spraying process. A semiconductor package PK5 is thus completed.

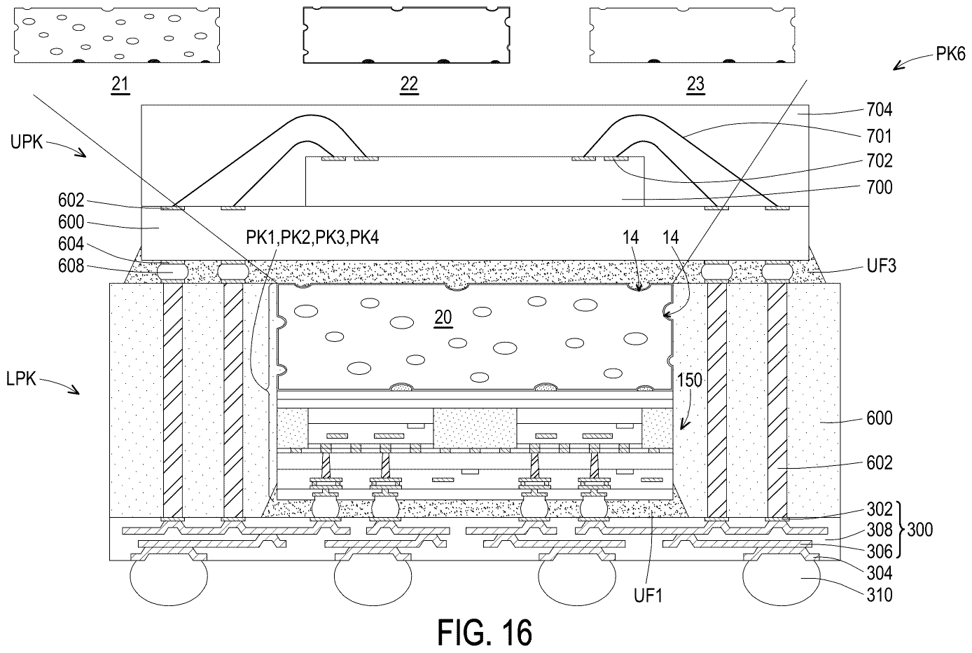

FIG. 16 illustrates a semiconductor package in accordance with some embodiments. The semiconductor package of FIG. 16 is a package-on-package (POP) structure, for example.

Referring to FIG. 16, a lower package LPK including an interposer structure 300 and a semiconductor package PK1 is provided. The materials and forming method of the interposer structure 300 have been described above, so the details are not iterated herein. In some embodiments, the semiconductor package PK1 is picked and placed on the interposer structure 300 with the heat dissipation substrate 20 facing up. Specifically, the semiconductor package PK1 is bonded to the interposer structure 300 through the die pads 111, the bumps 116 and the metal pads 302. The semiconductor package PK1 with the heat dissipation substrate 20 may be replaced by a semiconductor package PK2 with a heat dissipation substrate 21 (as shown in FIG. 12), a semiconductor package PK3 with a heat dissipation substrate 23 (as shown in FIG. 13) or a semiconductor package PK4 with a heat dissipation substrate 24 (as shown in FIG. 14) in other embodiments.

In some embodiments, the lower package LPK further includes through vias 602 around the semiconductor package PK1 and electrically connected to the interposer structure 300. In some embodiments, the method of forming the through vias 602 includes forming a mask pattern (e.g., photoresist film) with openings interposer structure 300, then forming a metallic material in the openings by electroplating or deposition, and removing the mask pattern to form the through vias 602 on the interposer structure 300.

In some embodiments, the lower package LPK further includes an encapsulation layer 600 around the semiconductor package PK1 and the through vias 602. In some embodiments, the encapsulation layer 600 includes a molding compound, a molding underfill, a resin or the like. In some embodiments, the encapsulation layer 600 includes a polymer material (such as polybenzoxazole (PBO), polyimide, benzocyclobutene (BCB), the like, or a combination thereof), an insulating material (such as silicon oxide, silicon nitride, the like, or a combination thereof), or a combination thereof. In some embodiments, the encapsulation layer 600 is formed by an over-molding process followed by a planarization process. Accordingly, the surface of the encapsulation layer 600 is flush with surfaces the through vias 602.

In some embodiments, an upper package UPK is provided and bonded to the lower package LPK. In some embodiments, the upper package UPK includes integrated circuit structures 600 and 700 vertically stacked and electrically connected to each other.

Specifically, the integrated circuit structure 700 is stacked on the integrated circuit structure 600, and bonding wires 701 are used to provide electrical connections between the pads 702 of the integrated circuit structure 700 and the pads 602 of the integrated circuit structure 600. The integrated circuit structure 600 is bonded to the through vias 602 through pads 604 and bumps 608. In some embodiments, an encapsulation layer 704 is formed to encapsulate the integrated circuit structure 700 and the bonding wires 701 to protect these components.

In some embodiments, an underfill layer UF is further provided to fill in the space between the lower package LPK and the upper package UPK around the bumps 608. In some embodiments, the underfill layer UF includes a molding compound such as epoxy, and is formed using dispensing, injecting, and/or spraying process. A semiconductor package PK6 is thus completed.

The semiconductor packages of the disclosure are illustrated with reference to FIG. 11 to FIG. 16. In some embodiments, a semiconductor package PK1/PK2/PK3/PK4 includes a heat dissipation substrate 20/21/22/23 and an integrated circuit structure 150. The heat dissipation substrate 20/21/22/23 includes a substrate 10 having a plurality of recesses 14 at a first surface thereof, a filling layer 18a disposed in the recesses 14 at the first surface and a first bonding layer BL1 disposed on the filling layer 18a. The integrated circuit structure 150 includes at least one die 100/200 and a second bonding layer BL2 on the at least one die 100/200. The integrated circuit structure 150 is bonded to the heat dissipation substrate 20/21/22/23 through the first bonding layer BL1 and the second bonding layer BL2.

In some embodiments, the substrate 10 has a thermal conductivity of about 230 W/m·K or more. In some embodiments, the substrate 10 includes AlN, GaN, a single crystal diamond, the like or a combination thereof.

In some embodiments, the substrate 10 of the heat dissipation substrate 20/21 is a porous substrate. Specifically, pores or voids 12 are present in the substrate 10 of the heat dissipation substrate 20/21. In other embodiments, the substrate 10 of the heat dissipation substrate 22/23 is a void-free substrate. Specifically, pores or voids are not present in the substrate 10 of the heat dissipation substrate 22/23.

In some embodiments, the heat dissipation substrate 20/22 further comprises a liner layer 16 disposed between the filling layer 18a and the substrate 10. In some embodiments, the liner layer 16 covers an entire surface of the substrate 10. In some embodiments, a surface of the liner layer 16 is substantially flush with a surface of the filling layer 18a. In some embodiments, the first bonding layer BL1 is in contact with the filling layer 18a. In some embodiments, the substrate 10 has a first surface roughness, and the first bonding layer BL1 has a second surface roughness less than the first surface roughness.

In some embodiments, the substrate 10 further has a plurality of recesses 14 at a second surface (e.g., side surface) thereof, the second surface is adjacent to the first surface (e.g., bottom surface or bonding surface), and an encapsulating layer 450 is filled in the recesses at the second surface of the substrate 10, as shown in FIG. 15.

In some embodiments, the substrate 10 further has a plurality of recesses 14 at a second surface (e.g., side surface) thereof, the second surface is adjacent to the first surface (e.g., bottom surface or bonding surface), and an encapsulating layer 600 is filled in the recesses at the second surface of the substrate 10, as shown in FIG. 16.

In some embodiments, the substrate 10 further has a plurality of recesses 14 at a third surface (e.g., top surface) thereof, the third surface is opposite to the first surface (e.g., bottom surface), and an underfill layer UF is filled in the recesses at the third surface of the substrate 10, as shown in FIG. 16.

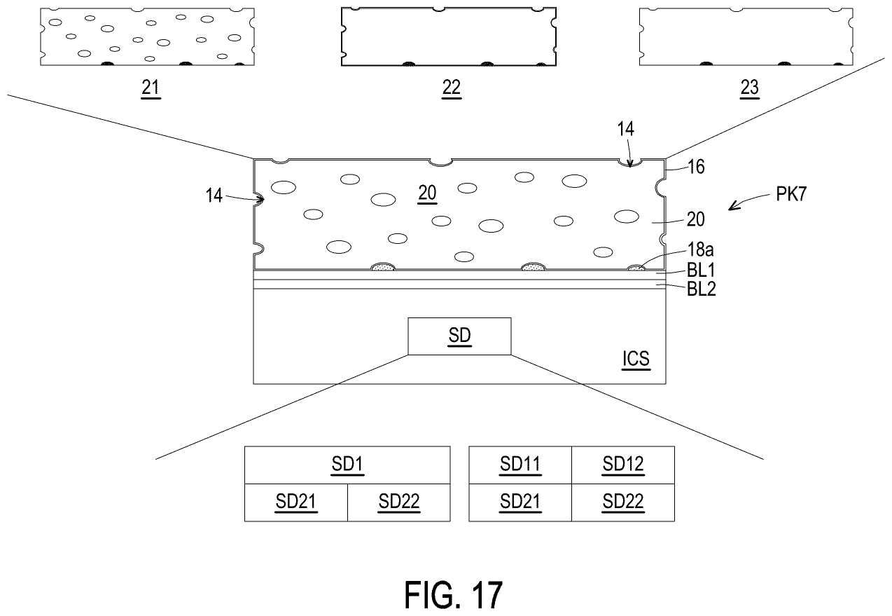

The above embodiments in which the heat dissipation substrate 20/21/22/23 of the disclosure are applied to 3DIC (e.g., FIGS. 11-14), chip-on-wafer-on-substrate (e.g., FIG. 15) or PoP (e.g., FIG. 16) structures are provided for illustration purposes, and are not construed as limiting the present disclosure. In other embodiments, the heat dissipation substrate 20/21/22/23 of the disclosure may be applied to any semiconductor package upon the process requirements. The general structure is described with reference with FIG. 17.

As shown in FIG. 17, in some embodiments, a semiconductor package PK7 includes a heat dissipation substrate 20/21/22/23 and an integrated circuit structure ICS. The heat dissipation substrate 20/21/22/23 includes a substrate 10 having a plurality of recesses 14 at a first surface thereof, a filling layer 18a disposed in the recesses 14 at the first surface and a first bonding layer BL1 disposed on the filling layer 18a. The integrated circuit structure ICS includes at least one semiconductor die SD and a second bonding layer BL2 on the at least one die SD. The at least one semiconductor die SD may be a single semiconductor die or a die stack, as shown in the enlarged views of FIG. 17. In some embodiments, the die stack may include a semiconductor die SD1 facing the heat dissipation substrate 20/21/22/23 and two semiconductor dies SD21 and SD22 facing away from the dissipation substrate 20/21/22/23. In other embodiments, the die stack may include two semiconductor dies SD11 and SD12 facing the heat dissipation substrate 20/21/22/23 and two semiconductor dies SD21 and SD22 facing away from the dissipation substrate 20/21/22/23. Other possible die stack arrangements are within the scope of the present disclosure. Besides, the integrated circuit structure ICS is bonded to the heat dissipation substrate 20/21/22/23 through the first bonding layer BL1 and the second bonding layer BL2.

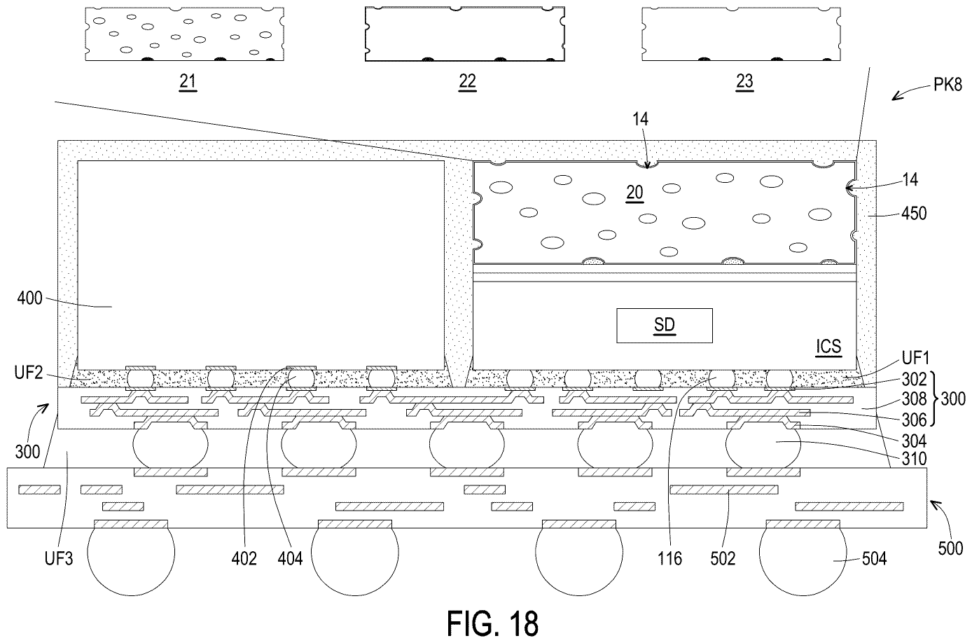

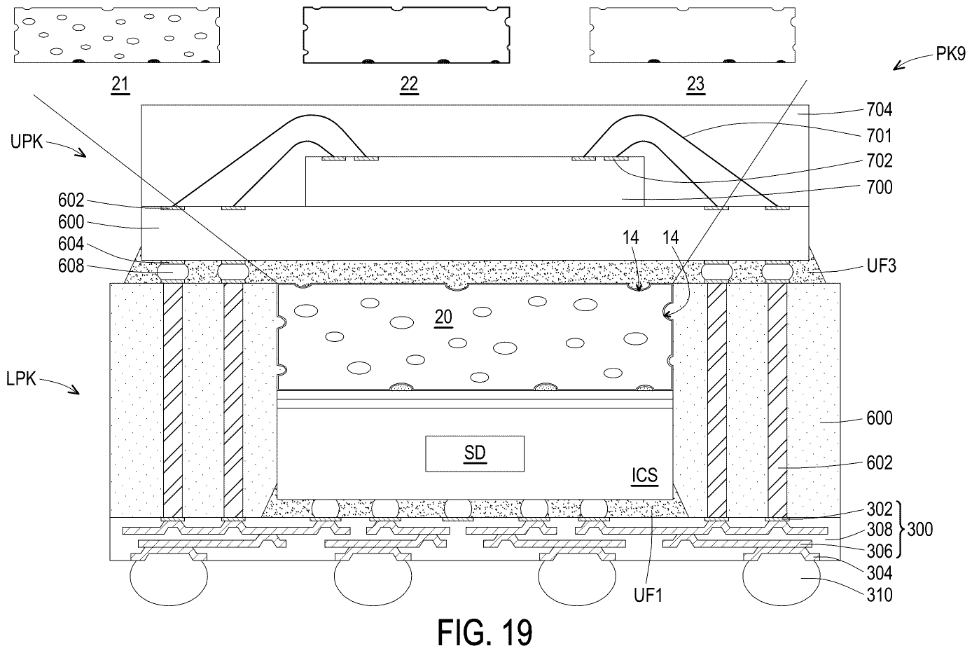

The general structure of FIG. 17 may be applied to a chip-on-wafer-on-substrate structure, as shown in the semiconductor package PK8 in FIG. 18. Similarly, the general structure of FIG. 17 may be applied to a POP structure, as shown in the semiconductor package PK9 in FIG. 19.

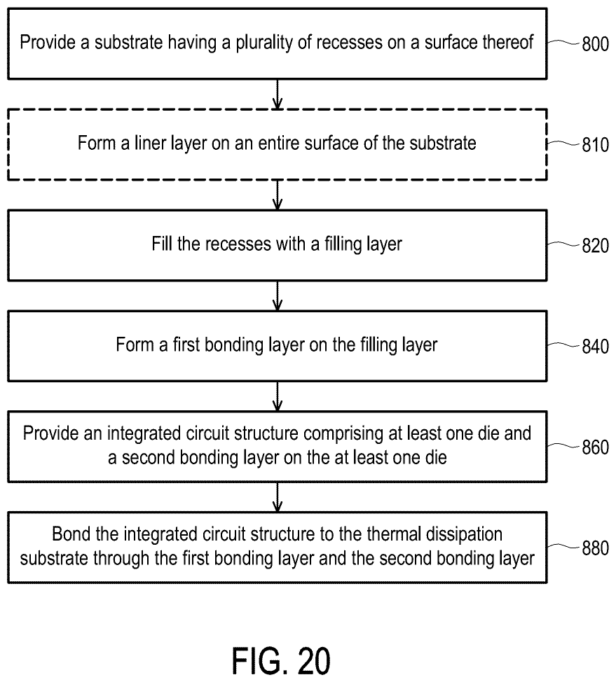

FIG. 20 illustrates a method of forming a semiconductor package in accordance with some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 800, a substrate is provided having a plurality of recesses on a surface thereof. FIG. 1 and FIG. 12 to FIG. 19 illustrate cross-sectional views corresponding to some embodiments of act 800. In some embodiments, the substrate has a thermal conductivity of about 230 W/m·K or more. In some embodiments, the substrate is a porous substrate formed by a sintering process. In other embodiments, the substrate is a void-free substrate formed by a deposition process.

At act 810, a liner layer is formed on an entire surface of the substrate. FIG. 2 and FIG. 13 and FIG. 15 to FIG. 19 illustrate cross-sectional views corresponding to some embodiments of act 810. Act 810 is optional and may be omitted as needed.

At act 820, the recesses is filled with a filling layer. FIG. 3 to FIG. 4 and FIG. 12 to FIG. 19 illustrate cross-sectional views corresponding to some embodiments of act 820. In some embodiments, the method of filling the recesses with the filling layer includes forming a filling material over the substrate filling the recesses, and removing the filling material outside of the recesses. In some embodiments, when act 810 is omitted, the filling layer is in physical contact with the substrate without a liner layer therebetween.

At act 840, a first bonding layer is formed on the filling layer. FIG. 5 and FIG. 12 to FIG. 19 illustrate cross-sectional views corresponding to some embodiments of act 840. In some embodiments, the substrate has a first surface roughness, and the first bonding layer has a second surface roughness less than the first surface roughness.

At act 860, an integrated circuit structure including at least one die and a second bonding layer on the at least one die. FIG. 6 to FIG. 9 and FIG. 12 to FIG. 19 illustrate cross-sectional views corresponding to some embodiments of act 860.

At act 880, the integrated circuit structure is bonded to the substrate through the first bonding layer and the second bonding layer. FIG. 10 to FIG. 11 and FIG. 12 to FIG. 19 illustrate cross-sectional views corresponding to some embodiments of act 880.

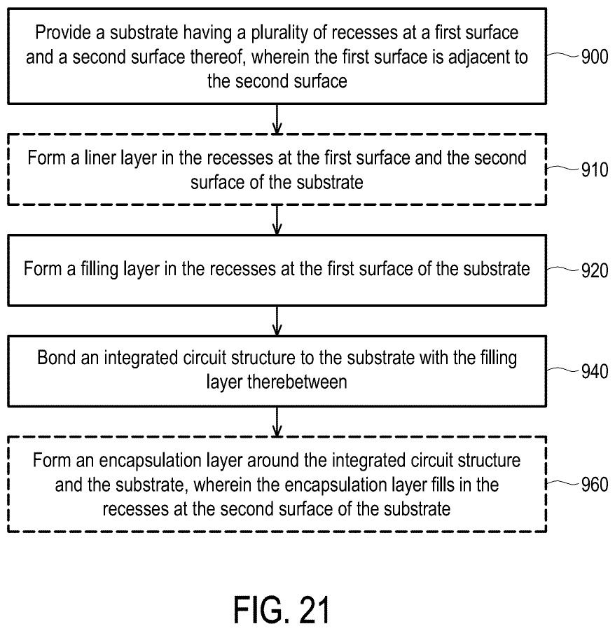

FIG. 21 illustrates a method of forming a semiconductor package in accordance with some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 900, a substrate is provided, wherein the substrate has a plurality of recesses at a first surface and a second surface thereof, and the first surface is adjacent to the second surface. FIG. 1 and FIG. 12 to FIG. 19 illustrate cross-sectional views corresponding to some embodiments of act 900. In some embodiments, the substrate has a thermal conductivity of about 230 W/m·K or more. In some embodiments, the substrate is a porous substrate formed by a sintering process. In other embodiments, the substrate is a void-free substrate formed by a deposition process. In some embodiments, the first surface of the substrate is a bonding surface, and the second surface of the substrate is a surface adjacent to the bonding surface.

At act 910, a liner layer is formed in the recesses at the first surface and the second surface of the substrate. FIG. 2 and FIG. 13 and FIG. 15 to FIG. 19 illustrate cross-sectional views corresponding to some embodiments of act 910. In some embodiments, the liner layer is formed on an entire surface of the substrate. Act 910 is optional and may be omitted as needed.

At act 920, a filling layer is formed in the recesses at the first surface of the substrate. FIG. 3 to FIG. 4 and FIG. 12 to FIG. 19 illustrate cross-sectional views corresponding to some embodiments of act 920.

At act 940, an integrated circuit structure is bonded to the substrate with the filling layer therebetween. FIG. 5 to FIG. 11 and FIG. 12 to FIG. 19 illustrate cross-sectional views corresponding to some embodiments of act 940. In some embodiments, the integrated circuit structure is bonded to the substrate through a fusion bonding including a dielectric-to-dielectric bonding.

At act 960, an encapsulation layer is formed around the integrated circuit structure and the substrate, and the encapsulation layer fills in the recesses at the second surface of the substrate. FIG. 15 to FIG. 16 illustrate cross-sectional views corresponding to some embodiments of act 960. Act 960 is optional and may be omitted as needed.

In view of the foregoing, in the disclosure, a heat dissipation substrate with high thermal conductivity is provided for a semiconductor package. With the method of the disclosure, the surface roughness is resolved and the heat dissipation substrate provides a planar surface for the subsequent bonding process, so the conventional delamination or cracking issue around the bonding surface is not present. With the heat dissipation substrate of the disclosure, the heat dissipation performance of the semiconductor package is enhanced, and the reliability of the semiconductor package is improved.

Many variations of the above examples are contemplated by the present disclosure. It is understood that different embodiments may have different advantages, and that no particular advantage is necessarily required of all embodiments.

In accordance with some embodiments of the present disclosure, a semiconductor package includes a heat dissipation substrate and an integrated circuit structure. The heat dissipation substrate includes a substrate having a plurality of recesses at a first surface thereof, a filling layer disposed in the recesses at the first surface and a first bonding layer disposed on the filling layer. The integrated circuit structure includes at least one die and a second bonding layer on the at least one die. The integrated circuit structure is bonded to the heat dissipation substrate through the first bonding layer and the second bonding layer.

In accordance with some embodiments of the present disclosure, a semiconductor package includes providing a substrate having a plurality of recesses on a surface thereof; filling the recesses with a filling layer; forming a first bonding layer on the filling layer; providing an integrated circuit structure comprising at least one die and a second bonding layer on the at least one die; and bonding the integrated circuit structure to the carrier through the first bonding layer and the second bonding layer.

In accordance with some embodiments of the present disclosure, a method of forming a semiconductor package includes providing a substrate having a plurality of recesses at a first surface and a second surface thereof, wherein the first surface is adjacent to the second surface; forming a liner layer in the recesses at the first surface and the second surface of the substrate; forming a filling layer in the recesses at the first surface of the substrate; and bonding an integrated circuit structure to the substrate with the filling layer therebetween.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a heat dissipation substrate, comprising:
a substrate having a plurality of recesses at a first surface thereof;
a filling layer disposed in the recesses at the first surface; and
a first bonding layer, disposed on the filling layer; and
an integrated circuit structure, comprising a second bonding layer and bonded to the heat dissipation substrate through the first bonding layer and the second bonding layer.

2. The semiconductor package of claim 1, wherein the substrate is a porous substrate.

3. The semiconductor package of claim 1, wherein the substrate has a thermal conductivity of about 230 W/m·K or more.

4. The semiconductor package of claim 1, wherein the heat dissipation substrate further comprises a liner layer disposed between the filling layer and the substrate.

5. The semiconductor package of claim 4, wherein the liner layer covers an entire surface of the substrate.

6. The semiconductor package of claim 4, wherein a surface of the liner layer is substantially flush with a surface of the filling layer.

7. The semiconductor package of claim 1, wherein the first bonding layer is in contact with the filling layer.

8. The semiconductor package of claim 1, wherein the substrate has a first surface roughness, and the first bonding layer has a second surface roughness less than the first surface roughness.

9. The semiconductor package of claim 1, wherein the substrate further has a plurality of recesses at a second surface thereof, the second surface is adjacent to the first surface, and an encapsulating layer is filled in the recesses at the second surface of the substrate.

10. A method of forming a semiconductor package, comprising:
providing a substrate having a plurality of recesses on a surface thereof;
filling the recesses with a filling layer;
forming a first bonding layer on the filling layer;
providing an integrated circuit structure comprising at least one die and a second bonding layer on the at least one die; and
bonding the integrated circuit structure to the substrate through the first bonding layer and the second bonding layer.

11. The method of claim 10, wherein the substrate is a porous substrate formed by a sintering process.

12. The method of claim 10, wherein the substrate is a void-free substrate formed by a deposition process.

13. The method of claim 10, wherein the substrate has a first surface roughness, and the first bonding layer has a second surface roughness less than the first surface roughness.

14. The method of claim 10, wherein filling the recesses with the filling layer comprises:
forming a filling material over the substrate filling the recesses; and
removing the filling material outside of the recesses.

15. The method of claim 10, further comprising, before filling the recesses with the filling layer, forming a liner layer on an entire surface of the substrate.

16. A method of forming a semiconductor package, comprising:
providing a substrate having a plurality of recesses at a first surface and a second surface thereof, wherein the first surface is adjacent to the second surface;
forming a liner layer in the recesses at the first surface and the second surface of the substrate;
forming a filling layer in the recesses at the first surface of the substrate; and
bonding an integrated circuit structure to the substrate with the filling layer therebetween.

17. The method of claim 16, wherein the substrate is a porous substrate formed by a sintering process.

18. The method of claim 16, wherein the substrate is a void-free substrate formed by a deposition process.

19. The method of claim 16, wherein the integrated circuit structure is bonded to the substrate through a fusion bonding.

20. The method of claim 16, further comprising forming an encapsulation layer around the integrated circuit structure and the substrate, wherein the encapsulation layer fills in the recesses at the second surface of the substrate.
